(19) United States
(12) Patent Application Publication
(10) Pub. No.: US 2026/0142274 A1
(43) Pub. Date: May 21, 2026

(54) IMMERSION COOLING MODULE

(71) Applicants: SK INNOVATION CO., LTD., Seoul (KR); SK ENMOVE CO., LTD., Seoul (KR)

(72) Inventors: In Sik JUNG, Daejeon (KR); Gi Hong MIN, Daejeon (KR)

(21) Appl. No.: 19/372,292

(22) Filed: Oct. 29, 2025

(30) Foreign Application Priority Data
Nov. 15, 2024 (KR) 10-2024-0163199

(51) Int. Cl. H01M 10/6568; H01M 10/613; H01M 10/6569

(52) U.S. Cl. CPC H01M 10/6568; H01M 10/613; H01M 10/6569

(57) ABSTRACT

A battery device is provided with cooling bodies for contacting the outer surfaces of a plurality of battery cells arranged inside a battery case, and spacers provided adjacent to the cooling bodies. The cooling bodies absorb or are impregnated with a cooling fluid inside the battery case. Cooling medium vapor flow channels in which cooling medium vapor circulates are formed on the surfaces of the Foreign Application Priority Data spacers facing the cooling bodies, the cooling medium vapor being generated by the evaporation of the cooling fluid of the cooling bodies.

### CROSS REFERENCE TO RELATED APPLICATION

The present application claims priority to Korean Patent Application No. 10-2024-0163199, filed Nov. 15, 2024, the entire content of which is incorporated herein for all purposes by this reference.

### BACKGROUND

### Technical Field

The embodiments of the present disclosure relate to an immersion cooling module.

### Description of the Related Art

In recent years, as mobile devices such as mobile phones and laptops have become smaller and lighter, and electric vehicles and hybrid vehicles demand high-capacity power sources, a variety of batteries are being developed and used.

In the case of secondary batteries, efficiency is becoming increasingly important depending on the application field. However, problems such as heat generation and fires during charging or operation also may occur due to external factors.

Accordingly, technologies are being developed to increase the operating efficiency of secondary batteries and ensure safety. Moreover, a recent surge in electricity usage has led to increased carbon emissions and exacerbated global warming concerns, which has called for more efficient device operation mechanisms, and improved cooling methods and maximization of cooling efficiency therefor.

### SUMMARY

According to an embodiment of the present disclosure, provided is an immersion cooling module that can enhance the cooling efficiency for a battery module by cooling the battery module by immersion cooling and utilizing latent heat in a phase change of a cooling fluid during the immersion cooling process.

In addition, by effectively arranging and combining individual housings for immersion cooling of a battery module, the cooling efficiency of the entire cooling fluid can be improved, and the cooling effect for a battery module housed in each of the housings can also be maximized.

To achieve the above objectives, according to an embodiment of the present disclosure, there is provided an immersion cooling module including a housing configured to contain a cooling fluid at a predetermined level; at least one unit housing accommodated inside the housing to be impregnated with the cooling fluid, configured to have a flow passage through which the cooling fluid flows in and out and an open top, and configured to accommodate a battery module therein; and a condenser coupled to liquefy a gas formed by vaporization of the cooling fluid in the housing and reintroduce the liquefied gas into the housing in a liquid state, wherein opposite sides of the battery module may be spaced apart from respective facing inner sides of the unit housing by a predetermined distance to form a flow path for the cooling fluid, and a porous moisture absorption member attached to each of the opposite sides of the battery module may be further included.

In this case, the battery module may be formed by stacking a plurality of battery cells vertically, and the porous moisture absorption member may be combined to surround stacked surfaces of the battery cells and opposite sides of the battery cells in a stacked direction.

In addition, the flow passage of the unit housing may be formed in opposite directions of a lowermost battery cell among the battery cells of the battery module accommodated inside the unit housing.

In addition, the condenser may be coupled inside the housing, but be provided above the unit housing, so that a gas may flow in toward an upper direction of the flow path at opposite ends of the unit housing, and the liquefied fluid may be reintroduced from above the battery module of the unit housing.

According to another embodiment of the present disclosure, there is provided an immersion cooling module including a housing configured to contain a cooling fluid at a predetermined level; an inner housing impregnated with the cooling fluid, provided spaced apart from a lower surface of the housing, and in which a plurality of battery modules is accommodated spaced apart from each other, and a condenser coupled to liquefy a gas formed by vaporization of the cooling fluid in the housing and reintroduce the liquefied gas into the housing in a liquid state, wherein at least one flow passage through which the cooling fluid flows in and out may be provided on a lower surface of the inner housing in the separation space between the battery modules, and a porous moisture absorption member attached to facing sides of the battery modules that form the separation space where the flow passage is provided may be further included.

In this case, the inner housing may have a narrower width than the housing.

According to still another embodiment of the present disclosure, there is provided an immersion cooling module including a housing configured to contain a cooling fluid at a predetermined level; a first housing configured to have a narrower width than the housing to be impregnated with the cooling fluid, and to have an open top to accommodate a first battery module inside; a second housing provided on the first battery module, accommodated inside the first housing, configured to have a narrower width than the first housing to be impregnated with the cooling fluid, and configured to have an open top to accommodate a second battery module inside; a third housing provided on the second battery module, accommodated inside the second housing, configured to have a narrower width than the second housing to be impregnated with the cooling fluid, and configured to have an open top to accommodate a third battery module inside; an inlet pipe through which the cooling fluid flows into the housing; a first inlet pipe provided in the first housing so that the cooling fluid flows into the first housing in an inflow direction of the cooling fluid flowing in through the inlet pipe; a second inlet pipe provided so that the cooling fluid flowing between the housing and the first housing in the inflow direction of the cooling fluid of the inlet pipe flows directly to the second housing; a third inlet pipe provided so that the cooling fluid flowing between the housing and the first housing in the inflow direction of the cooling fluid of the inlet pipe flows directly to the third housing; and a condenser combined to liquefy a gas resulting from the cooling fluid inside the first housing, the second housing and the third housing being vaporized and flowing upward and to reintroduce the liquefied gas into the housing in a liquid state.

In this case, the module may further include an outlet pipe provided in an opposite direction of the inlet pipe so that the cooling fluid of the housing flows out; a first outlet pipe provided to communicate from the first housing to the housing in an outflow direction of the cooling fluid of the outlet pipe; a second outlet pipe provided to communicate from the second housing to the first housing in the outflow direction of the cooling fluid of the outlet pipe; and a third outlet pipe provided to communicate from the third housing to the second housing in the outflow direction of the cooling fluid of the outlet pipe.

In addition, the first, second, and third battery modules may be formed by stacking a plurality of battery cells vertically, and the porous moisture absorption member may be combined to surround stacked surfaces of the battery cells and opposite sides of the battery cells in a stacked direction.

In yet another embodiment of the present disclosure, there is provided an immersion cooling module including: an outer housing comprising two or more battery modules spaced apart from each other and from internal walls of the outer housing; a condenser operatively coupled via a conduit to an upper portion of an interior space of the outer housing; an inner housing disposed inside the outer housing, spaced apart from the outer housing and from vertical side walls of the battery modules, wherein the outer housing and the inner housing form a container fillable with a cooling fluid with an open top; a plurality of battery cells stacked in each of the battery modules; a porous moisture absorption member disposed between the stacked battery cells; and wherein the inner housing has at least one flow passage through which the cooling fluid flows to a separation space between the battery modules.

The features and advantages of the embodiments of the present disclosure will become more apparent from the following detailed description based on the accompanying drawings.

Terms or words used in this specification and claims should not be construed in their usual, dictionary meaning, and should be interpreted with meaning and concept consistent with the technical idea of the present disclosure based on the principle that the inventor can define terminology appropriately to describe his or her invention in the best way possible.

According to an embodiment of the present disclosure, it is possible to enhance the cooling efficiency for a battery module immersed in a cooling fluid, thereby improving the reliability of operation of the entire device including the battery module.

Furthermore, in addition to cooling when the cooling fluid in each battery module circulates in a liquid state during immersion of battery modules, the cooling effect can be effectively induced by latent heat absorption during a phase change of the cooling fluid.

Furthermore, by improving the efficiency and reliability of the immersion cooling of a battery module, the power consumption of the entire device can be effectively reduced, thereby reducing carbon emissions.

Furthermore, by applying housings of different widths to individual battery modules housed within the housings, the independent operational reliability of the battery modules is maintained, improving the operational reliability of the entire device and maximizing the lifespan of the device, thereby reducing waste and actively addressing environmental issues.

### BRIEF DESCRIPTION OF THE DRAWINGS

The above and other objectives, features, and other advantages of the embodiments of the present disclosure will be more clearly understood from the following detailed description when taken in conjunction with the accompanying drawings, in which:

FIG. 1 is a schematic view of an immersion cooling module according to an embodiment of the present disclosure;

FIG. 2 is a modified schematic view of an immersion cooling module according to an embodiment of the present disclosure;

FIG. 3 is a schematic view of an immersion cooling module according to another embodiment of the present disclosure;

FIG. 4 is a schematic view of an immersion cooling module according to still another embodiment of the present disclosure; and

FIG. 5 is a partial schematic plan view of an immersion cooling module according to FIG. 4.

### DETAILED DESCRIPTION

Terms used to describe an embodiment of the present disclosure are not intended to limit the scope of the disclosure. It should be noted that singular expressions include plural expressions unless the context clearly dictates otherwise.

It should be noted that, in assigning reference numerals to components in the drawings, identical components are assigned the same reference numerals as much as possible even if they are shown in different drawings, and similar reference numbers are assigned to similar components.

The drawings may be schematic or exaggerated for the purpose of illustrating the embodiments. In this disclosure, expressions such as “have”, “may have”, “include”, or “may include” refer to the presence of the corresponding feature (e.g., a numerical value, function, operation, or component such as a part), and do not exclude the presence of additional features.

Terms such as “one”, “other”, “another”, “first”, “second”, etc., are used to distinguish one component from another component, and the components are not limited by the terms.

Hereinafter, an embodiment of the present disclosure will be described in detail with reference to the attached drawings.

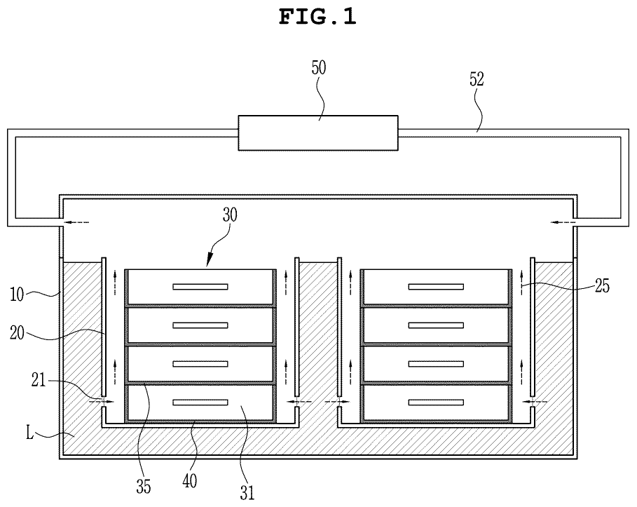

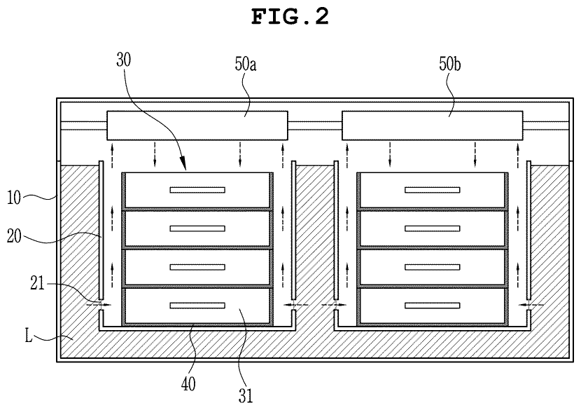

FIG. 1 is a schematic view of an immersion cooling module according to an embodiment of the present disclosure, and FIG. 2 is a modified schematic view of an immersion cooling module according to an embodiment of the present disclosure.

An immersion cooling module according to an embodiment of the present disclosure includes a housing 10 (also referred to as an outer housing) containing a cooling fluid L at a predetermined level, at least one unit housing 20 that is accommodated inside the housing 10 to be impregnated with the cooling fluid L. The at least one unit housing has a flow passage 21 formed through which the cooling fluid L flows in and out, and is configured to have an open top and accommodate a battery module 30 therein. The immersion cooling module according to FIG. 1 also includes a condenser 50 that is coupled to the housing 10 to liquefy a gas formed by vaporization of the cooling fluid L in the housing 10 and reintroduce the liquefied gas into the housing 10 in a liquid state. Opposite sides of the battery module 30 are spaced apart from the respective facing inner sides of the unit housing 20 by a predetermined distance to form a flow path for the cooling fluid L, and the immersion cooling module may further include a porous moisture absorption member 40. The porous moisture absorption member 40 may be attached to each of the opposite sides of the battery module 30.

As shown in FIG. 1, the cooling fluid L is accommodated inside the housing 10. The cooling fluid L is provided at a predetermined level inside the housing 10, and a predetermined space may be formed so that a gas may be filled at a predetermined height above.

The unit housing 20 may be arranged to be impregnated with the cooling fluid L of the housing 10. The unit housing 20 may be formed to accommodate the battery module 30 therein while being impregnated with the cooling fluid L within the housing 10, so that the cooling fluid L flows inside the unit housing 20 and the battery module 30 is impregnated.

To be specific, as shown in FIG. 1, the unit housing 20 may be arranged to be impregnated with the cooling fluid L inside the housing 10, and the battery module 30 may be accommodated inside the unit housing 20.

The unit housing 20 may have flow passage 21 so that the cooling fluid L inside the housing 10 may flow freely. The flow passage 21 may be formed on each end of the lower part of the unit housing 20. When the battery module 30 is accommodated inside the unit housing 20 and the flow passage is formed in the unit housing 20 between the opposite sides of the battery module 30 and the inner side of the unit housing 20, the cooling fluid is introduced into the unit housing 20 from the bottom thereof to effectively cool the battery module 30.

The flow passage 21 may be formed in opposite directions of the lowermost battery cell 31 of the battery module 30 housed inside the unit housing 20. Due to this, a flow path is formed between the inner surface of the unit housing 20 and one side of the battery module 30 facing the corresponding inner surface of the unit housing 20 and the flow direction of the cooling fluid L is directed upward. Also, heat absorption of the cooling fluid L that cools the battery module 30 increases as it goes upward, so that the cooling of the battery module may be performed through secondary phase change. As the cooling fluid L flows upward around the battery module 30, the cooling fluid absorbs an increasing amount of heat that enables secondary phase change for enhanced thermal management.

In the flow path 25 between the inner surface of the unit housing 20 and one side of the battery module 30 through which the cooling fluid L flows in an upward direction, the porous moisture absorption member 40 may be attached to the side of the battery module 30 facing the inner surface of the unit housing 20, that is, the side of the battery module 30 which defines one side of the flow path and comes into contact with the flowing fluid. Furthermore, by combining the porous moisture absorption member 40 to each of the stacking surfaces 35 on which the battery cells 31 are stacked, the cooling fluid L flows into and is impregnated into the porous moisture absorption member 40 positioned in the stacking surfaces 235, thereby effectively performing cooling on each stacking surface 35 of the battery cells 31.

Although in the illustrated embodiment of FIG. 1 of the present disclosure, the battery cells 31 of the battery module 30 are shown in a structure in which the battery cells 31 are stacked vertically, it should be understood that the stacking direction and shape may be appropriately changed as needed. However, even in this case, the formation of a flow path through which the cooling fluid L can flow upwards inside the unit housing 20 and the attachment of the porous moisture absorption member 40 to one side of the battery module 30 in contact with the flow path should be applied equally.

By doing so, the action of vaporizing the cooling fluid L that is flowing upward and supplying gas to the internal space of the housing 10 may be done more effectively.

In addition, the battery module 30 may be cooled by allowing the cooling fluid L to flow and circulate in the flow path between the inner surface of the unit housing 20 and the porous moisture absorption member 40 on one side of the battery module 30 facing the inner surface of the unit housing 20, and due to heat generation at the coupling surface of the battery module 30, the cooling fluid L absorbed by the porous moisture absorption member 40 may cool the battery module 30 using the latent heat in the phase change process in which the cooling fluid L absorbs heat, causing the cooling fluid L to change state.

In this way, the vaporized gas resulting from the phase change of the cooling fluid L may naturally rise to the upper part of the flow path inside the unit housing 20 and fill a predetermined space inside the housing 10.

As shown in FIG. 1, by discharging the gas filled in the predetermined space at the upper part of the housing 10 toward one side of the space of the housing 10 and liquefying the gas by means of a condenser 50, the liquefied cooling fluid L may be reintroduced toward the other side of the space inside the housing 10. In this case, by combining the condenser 50 outside the housing 10 and reintroducing and circulating the liquefied cooling fluid L inside the housing 10, the effective circulation and cooling efficiency of the cooling fluid L inside the housing 10 may be enhanced.

The condenser 50 may receive the gas through a hollow pipe connected from a space inside the housing 10 that is near one side of the housing 10 and reintroduce the liquefied cooling fluid L into the other side of the space inside the housing 10 through a hollow pipe 52, which is the hollow pipe connected through the condenser 50. The passage for the movement of the gas may be a conduit such as a hollow pipe, and a heat exchanger or circulation device for other functions may be additionally connected and combined.

As shown in FIG. 2, in a modified embodiment of FIG. 1, the condenser 50 may be coupled inside the housing 10 above the unit housing 20, so that the vaporized gas may flow into the condenser 50 through the upper part of the flow path formed at opposite ends of the unit housing 20, and the liquefied cooling fluid L at the upper part of the battery module 30 of the unit housing 20 may be reintroduced by the condenser 50.

For example the condenser 50 may include first and second condenser sections (or simply first and second condensers) 50a and 50b and may be directly coupled above the unit housing 20 in the internal space of the housing 10, so that the cooling fluid L is vaporized through the flow path formed on each side of the unit housing 20, and the vaporized gas may be directly introduced into the first and second condensers 50a and 50b. The first and second condensers 50a and 50b liquefy the introduced gas, thereby re-introducing the liquefied cooling fluid L toward the battery module 30, thereby cooling the battery module 30.

As shown in FIG. 2, in the case that there are multiple unit housings 20 inside the housing 10, the condensers 50a and 50b may be respectively connected to the unit housings 20. Hence, based on FIG. 2, there may be two or more condensers each one corresponding to one unit housing inside the housing of the immersion cooling module.

In addition, the design may be changed by combining the condensers 50a and 50b used in combination with or integrated into the combined structure of the condenser 50 connected to the outside of the housing 10 already described above.

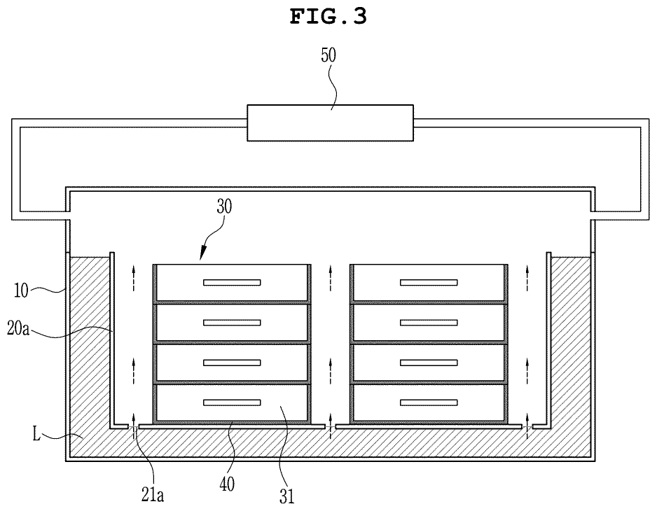

FIG. 3 is a schematic view of an immersion cooling module according to another embodiment of the present disclosure.

The immersion cooling module according to another embodiment of the present disclosure as illustrated in FIG. 3 may include a housing 10 containing a cooling fluid L at a predetermined level, an inner housing 20a provided spaced apart from the lower surface of the housing 10 to allow a flow path for the cooling fluid L below the bottom surface of the inner housing 20a. Inside the inner housing 20a, a plurality of battery modules 30 (e.g., two battery modules) are accommodated and spaced apart from each other. The top of the inner housing 20a is open. The flow path for the cooling fluid may surround the inner housing 20a and comprise a bottom flow bath extending below the bottom surface of the inner housing 20a, and side flow paths on both opposite sides of the inner housing 20a. A condenser 50 may be coupled via conduit 52 to the housing 10 and, in particular to the space of the housing 10 that is above the inner housing 20a. The condenser 50 may liquefy a gas formed by vaporization of the cooling fluid L in the housing 10 and may reintroduce the liquefied gas into the housing 10 in a liquid state. At least one flow passage 21a through which the cooling fluid L flows in and out is formed on the lower surface of the inner housing 20a in a separation space between the adjacent battery modules 30. The cooling immersion module may further include a plurality of porous moisture absorption members 40 attached to facing sides of the battery modules 30 in the separation space where the flow passage 21a is formed.

As shown in the embodiment of FIG. 3, the inner housing 20a with an open top may be installed separately inside the housing 10 in which the cooling fluid L is contained at a predetermined level.

It is appropriate that the inner housing 20a is configured and arranged with a narrower width than the housing 10 inside the housing 10, so that a separation space between the housing 10 and the inner housing 20a is formed. In addition, the inner housing 20a is provided to be spaced apart from the lower surface of the housing 10 so that the cooling fluid L may flow through the spaces of the side surface and the lower surface of the inner housing 20a.

At least one inner housing 20a may be provided, and at least one battery module 30 may be placed inside the inner housing 20a. A flow passage 21a may be formed so that the cooling fluid L can flow into the inner housing 20a.

The flow passage 21a may be formed on the lower surface of the inner housing 20a to allow the cooling fluid L to flow in. In the case that multiple battery modules 30 are arranged inside the inner housing 20a, the flow passage 21a may be formed on the lower surface of the inner housing 20a corresponding to the separation space between the battery modules 30.

Since the cooling fluid L is introduced at once through the flow passage 21a at each location of the inner housing 20a, the cooling temperature of the cooling fluid introduced into individual battery module 30 placed inside the inner housing 20a is uniform, so that effective cooling may be performed.

The cooling fluid L is simultaneously introduced at multiple locations of the inner housing 20a, so that the temperature deviation of the cooling fluid L flowing inside the inner housing 20a is small, and thus the cooling efficiency and balance between the battery modules 30 may be effectively maintained.

The flow passage 21a may be formed in the space between the battery modules 30 of the inner housing 20a, and the number and the diameter or area of the flow passage 21a may be appropriately selected and applied in consideration of the cooling efficiency and the range to be cooled, such as the size of the inner housing 20a or the number of battery modules 30.

As already described above, the porous moisture absorption member 40 may be attached to the side of the battery module 30 placed inside the inner housing 20a to contact it in the direction in which the cooling fluid L flows. In this way, the cooling fluid L is absorbed and remains in the porous moisture absorption member 40 coupled to the side of the battery module 30, thereby cooling the battery module 30, and in the cooling process, as the cooling fluid L naturally undergoes a phase change by absorbing heat through latent heat, the battery module 30 may be cooled.

Through this process, the vaporized cooling fluid L from the inner housing 20a fills the internal space of the housing 10, and the gas in the internal space of the housing 10 is circulated by means of the condenser 50 and reintroduced into the housing 10 as the liquefied cooling fluid L, thereby effectively circulating the cooling fluid L.

The technical configuration of another embodiment identical or corresponding to the immersion cooling module according to an embodiment of the present disclosure is substantially the same, and thus overlapping descriptions thereof will be omitted.

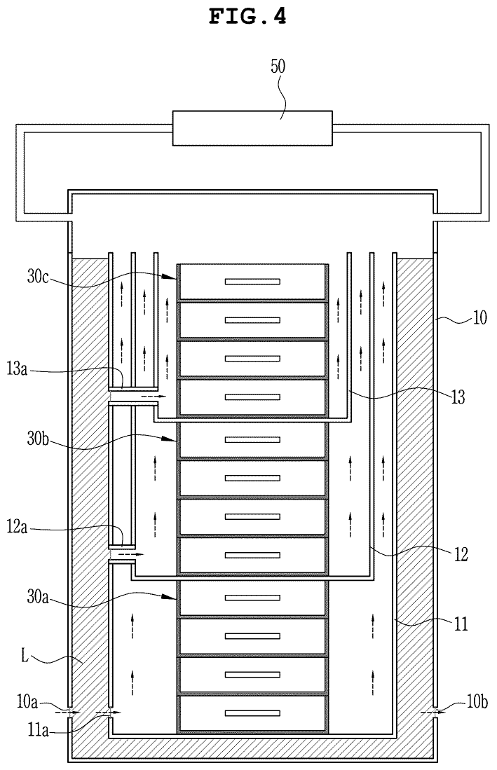

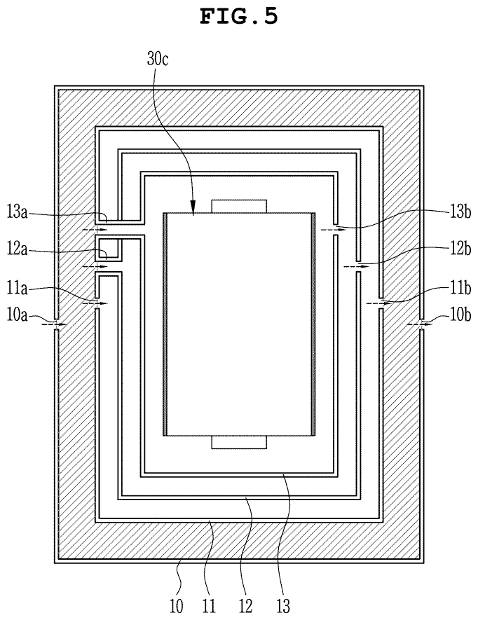

FIG. 4 is a schematic view of an immersion cooling module according to still another embodiment of the present disclosure, and FIG. 5 is a partial schematic plan view of an immersion cooling module according to FIG. 4.

The immersion cooling module according to still another embodiment of the present disclosure may include a housing 10 containing a cooling fluid L at a predetermined level; a first housing 11 impregnated with the cooling fluid L, having a narrower width than the housing 10, and having an open top to accommodate a first battery module 30a inside; a second housing 12 provided on the first battery module 30a, accommodated inside the first housing 11, impregnated with the cooling fluid L, having a narrower width than the first housing 11, and having an open top to accommodate a second battery module 30b inside; a third housing 13 provided on the second battery module 30b, accommodated inside the second housing 12, impregnated with the cooling fluid L, having a narrower width than the second housing 12, and having an open top to accommodate a third battery module 30c inside; an inlet pipe 10a through which cooling fluid flows into the housing 10; a first inlet pipe 11a provided in the first housing 11 so that the cooling fluid L flows into the first housing 11 in the inflow direction of the cooling fluid L flowing in through the inlet pipe 10a; a second inlet pipe 12a provided so that the cooling fluid L flowing between the housing 10 and the first housing 11 in the inflow direction of the cooling fluid L of the inlet pipe 10a flows directly to the second housing 12; a third inlet pipe 13a provided so that the cooling fluid L flowing between the housing 10 and the first housing 11 in the inflow direction of the cooling fluid L of the inlet pipe 10a flows directly to the third housing 13; and a condenser 50 configured to liquefy the gas resulting from the cooling fluid L inside the first housing 11, the second housing 12 and the third housing 13 being vaporized and flowing upward and to reintroduce the liquefied gas into the housing 10 in a liquid state.

As shown in FIG. 4, in the immersion cooling module according to still another embodiment of the present disclosure, a plurality of battery modules 30 is stacked vertically in multiple stages inside the housing 10, and the first housing 11, the second housing 12, and the third housing 13 that accommodate individual battery module 30 may be arranged in a form in which the width becomes narrower in a direction toward the top of the stacked battery modules 30.

The cooling fluid L may flow into the first housing 11, the second housing 12, and the third housing 13 in the same direction as the inflow direction of the cooling fluid L flowing through the inlet pipe 10a of the housing 10, and the cooling fluid L inside the first housing 11, the second housing 12, and the third housing 13 may be discharged in the same direction as the outflow direction to an outlet pipe 10b on the opposite side of the inlet pipe 10a of the housing 10.

To be specific, as shown in FIG. 4, the first housing 11 that has a narrower width than the housing 10 and has an open top may be provided inside the housing 10 containing the cooling fluid L of a predetermined level to be impregnated with the cooling fluid L. The first battery module 30a is provided inside the first housing 11, and the cooling fluid L is introduced into the first inlet pipe 11a of the first housing 11 to cool the first battery module 30a. The first inlet pipe 11a may be formed so that the cooling fluid is naturally introduced in the flow direction of the cooling fluid L flowing from the inlet pipe 10a of the housing 10. That is, the first inlet pipe 11a may be formed in the first housing 11 in the same direction as one side of the housing 10 in which the inlet pipe 10a is formed.

The second housing 12 that is narrower than the first housing 11 and has an open top is accommodated in the direction in which the first housing 11 is opened on the top of the first battery module 30a inside the first housing 11, and the second battery module 30b is accommodated inside the second housing 12. The second housing 12 may have the second inlet pipe 12a formed therein to allow the cooling fluid L to flow into the interior of the second housing 12. The cooling fluid L flowing into the second inlet pipe 12a is not the cooling fluid L flowing into the first housing 11 for cooling the first battery module 30a but the cooling fluid L inside the housing 10 that has not flowed into the first housing 11 flows directly into the second housing 12. To this end, the second inlet pipe 12a may be formed such that the cooling fluid L of the housing 10 flows directly into the second housing 12 without passing through the inside of the first housing 11. For example, the second inlet pipe 12a may be formed in a physical shape of a pipe so that the inside of the housing 10 and the inside of the second housing 12 are directly connected to guide the flow of the cooling fluid.

The third housing 13 is placed on top of the second battery module 30b, and may be formed to have a narrower width than the second housing 12 and an open top to accommodate the third battery module 30c inside of it.

The third inlet pipe 13a may be formed to allow the cooling fluid L to flow into the third housing 13. In this case, instead of the cooling fluid L flowing into the second housing 12 and cooling the second battery module 30b, the cooling fluid L inside the housing 10 that has not flowed into the first housing 11 (also referred to as first inner housing) and the second housing 12 (or second inner housing) may flow directly into the third housing 13 (or third inner housing).

To this end, the third inlet pipe 13a may be formed such that the cooling fluid L of the housing 10 flows directly into the third housing 13 without passing through the inside of the second housing 12. For example, the third inlet pipe 13a may be formed in a physical shape of a pipe so that the inside of the housing 10 and the inside of the third housing 13 are directly connected to guide the flow of the cooling fluid directly into the third housing 13.

By doing so, the cooling fluid L flowing into the first housing 11, the second housing 12, and the third housing 13 may flow at the cooling temperature of the initial cooling fluid L flowing into the housing 10.

In addition, as shown in FIG. 5, by arranging the first inlet pipe 11a, the second inlet pipe 12a, and the third inlet pipe 13a in the same direction as the flow direction of the cooling fluid L flowing into the inlet pipe 10a of the housing 10, the cooling fluid L may be naturally introduced into each of the inlet pipes 11a, 12a and 13a.

When introducing cooling fluid L into the inlet pipe 10a of the housing 10, if a separate driving force is used, the fluid introduced into the housing 10 is subjected to external pressure in the direction of the first housing 11, the second housing 12, and the third housing 13, thereby naturally introducing the cooling fluid L into the interior of each housing.

The housing 10 may have the outlet pipe 10b on the opposite side of the inlet pipe 10a so that the cooling fluid L inside the housing 10 may flow out.

A first outlet pipe 11b may be formed so that the internal fluid of the first housing 11 flows out from the first housing 11 to the housing 10, so that the cooling fluid L flows out in the direction of the outlet of the housing 10.

As shown in FIG. 5, second outlet pipe 12b may be formed to allow the cooling fluid L inside the second housing 12 to flow out toward the first housing 11, and a third outlet pipe 13b may be formed to allow the cooling fluid L inside the third housing 13 to flow out toward the second housing 12.

That is, the cooling fluid L may be sequentially discharged from the third housing 13 into the space of the second housing 12, then into the space of the first housing 11, and then into the space of the housing 10. By allowing the cooling fluid L to flow through each housing 10 step by step and finally to the outlet pipe 10b of the housing 10, the temperature difference of the entire cooling fluid L inside the housing 10 may be reduced.

As shown in FIGS. 4 and 5, the first housing 11 accommodates the cooling fluid L with a relatively largest capacity, and then the accommodation space is reduced by going to the second housing 12 and the third housing 13. Therefore, when the cooling fluid L is discharged, as the cooling fluid L passes through the second housing 12 and the first housing 11 from the third housing 13, which is the space where the temperature of the cooling fluid L rises the most, the cooling fluids L from the first, second, third housings are mixed with each other, alleviating the decrease in cooling temperature, thereby maintaining the balance of the cooling temperature of the cooling fluid L inside the housing 10, and thus maintaining a stable cooling efficiency overall.

Since the description of the first battery module 30a, the second battery module 30b, and the third battery module 30c is substantially the same as that of the battery module 30 described above, the description of the redundant description related to the porous moisture absorption member 40 combined with the battery module 30 and the stacked structure will be omitted.

Above, the embodiments of the present disclosure have been described in detail through specific embodiments. The embodiments are only illustrative and do not limit the scope of the appended claims. It will be apparent to those skilled in the art that various changes and modifications to the embodiments are possible within the scope and technical concepts of the present disclosure, and that such changes and modifications to the embodiments fall within the scope of the appended claims. Furthermore, the embodiments may be combined to form additional embodiments.

What is claimed is:

1. An immersion cooling module comprising:
a housing configured to contain a cooling fluid at a predetermined level;
at least one unit housing accommodated inside the housing to be impregnated with the cooling fluid, configured to have a flow passage through which the cooling fluid flows in and out and an open top, and configured to accommodate a battery module therein; and
a condenser coupled to liquefy a gas formed by vaporization of the cooling fluid in the housing and reintroduce the liquefied gas into the housing in a liquid state,
wherein opposite sides of the battery module are spaced apart from respective facing inner sides of the unit housing by a predetermined distance to form a flow path for the cooling fluid, and a porous moisture absorption member attached to each of the opposite sides of the battery module is further included.

2. The module of claim 1, wherein the battery module is formed by stacking a plurality of battery cells vertically, and the porous moisture absorption member is combined to surround stacked surfaces of the battery cells and opposite sides of the battery cells in a stacked direction.

3. The module of claim 1, wherein the flow passage of the unit housing is formed in opposite directions of a lowermost battery cell among the battery cells of the battery module accommodated inside the unit housing.

4. The module of claim 1, wherein the condenser is coupled inside the housing, and is provided above the unit housing, so that a gas flows in toward an upper direction of the flow path at opposite ends of the unit housing, and the liquefied fluid is reintroduced from above the battery module of the unit housing.

5. An immersion cooling module comprising:
a housing configured to contain a cooling fluid at a predetermined level;
an inner housing impregnated with the cooling fluid, provided spaced apart from a lower surface of the housing, and in which a plurality of battery modules is accommodated spaced apart from each other; and
a condenser coupled to liquefy a gas formed by vaporization of the cooling fluid in the housing and reintroduce the liquefied gas into the housing in a liquid state,
wherein at least one flow passage through which the cooling fluid flows in and out is provided on a lower surface of the inner housing in the separation space between the battery modules, and a porous moisture absorption member attached to facing sides of the battery modules that form the separation space where the flow passage is provided is further included.

6. The module of claim 5, wherein the inner housing has a narrower width than the housing.

7. An immersion cooling module comprising:
a housing configured to contain a cooling fluid at a predetermined level;
a first housing configured to have a narrower width than the housing to be impregnated with the cooling fluid, and to have an open top to accommodate a first battery module inside;
a second housing provided on the first battery module, accommodated inside the first housing, configured to have a narrower width than the first housing to be impregnated with the cooling fluid, and configured to have an open top to accommodate a second battery module inside;
a third housing provided on the second battery module, accommodated inside the second housing, configured to have a narrower width than the second housing to be impregnated with the cooling fluid, and configured to have an open top to accommodate a third battery module inside;
an inlet pipe through which the cooling fluid flows into the housing;
a first inlet pipe provided in the first housing so that the cooling fluid flows into the first housing in an inflow direction of the cooling fluid flowing in through the inlet pipe;
a second inlet pipe provided so that the cooling fluid flowing between the housing and the first housing in the inflow direction of the cooling fluid of the inlet pipe flows directly to the second housing;
a third inlet pipe provided so that the cooling fluid flowing between the housing and the first housing in the inflow direction of the cooling fluid of the inlet pipe flows directly to the third housing; and
a condenser combined to liquefy a gas resulting from the cooling fluid inside the first housing, the second housing and the third housing being vaporized and flowing upward and to reintroduce the liquefied gas into the housing in a liquid state.

8. The module of claim 7, further comprising:
an outlet pipe provided in an opposite direction of the inlet pipe so that the cooling fluid of the housing flows out;
a first outlet pipe provided to communicate from the first housing to the housing in an outflow direction of the cooling fluid of the outlet pipe;
a second outlet pipe provided to communicate from the second housing to the first housing in the outflow direction of the cooling fluid of the outlet pipe; and
a third outlet pipe provided to communicate from the third housing to the second housing in the outflow direction of the cooling fluid of the outlet pipe.

9. The module of claim 7, wherein the first, second, and third battery modules are formed by stacking a plurality of battery cells vertically, and the porous moisture absorption member is combined to surround stacked surfaces of the battery cells and opposite sides of the battery cells in a stacked direction.

10. An immersion cooling module comprising:
an outer housing comprising two or more battery modules spaced apart from each other and from the internal walls of the outer housing;
a condenser operatively coupled via a conduit to an upper portion of an interior space of the outer housing,
an inner housing disposed inside the outer housing spaced apart from the outer housing and from vertical side walls of the battery modules, wherein the outer housing and the inner housing form a container fillable with a cooling fluid with an open top;
a plurality of battery cells stacked in each of the battery modules; and
a porous moisture absorption member disposed between the stacked battery cells;
wherein the inner housing has at least one flow passage through which the cooling fluid flows to a separation space between the battery modules.
